(19) United States
(12) Patent Application Publication
(10) Pub. No.: US 2006/0144337 A1
(43) Pub. Date: Jul. 6, 2006

(54) HEATER FOR HEATING A WAFER AND METHOD FOR PREVENTING CONTAMINATION OF THE HEATER

(76) Inventors: Hsien-Che Teng, Tai-Nan City (TW); Chin-Fu Lin, Tai-Nan City (TW); Chun-Hao Chu, Kao-Hsiung Hsien (TW)

Correspondence Address: NORTH AMERICA INTELLECTUAL PROPERTY CORPORATION, P.O. BOX 506, MERRIFIELD, VA, 22116, US

(21) Appl. No.: 10/905,471

(22) Filed: Jan. 6, 2005

(51) Int. Cl. C23C 16/00

(52) U.S. Cl. 118/725

(57) ABSTRACT

A heater for heating a wafer is applied in a process chamber. The heater has an upper surface for positioning a wafer to heat the wafer, wherein a connection area of the upper surface and the wafer is less than the area of the wafer when the wafer is positioned on the upper surface of the heater.

### BACKGROUND OF INVENTION

1. Field of the Invention

The invention relates to a heater for heating a wafer, and more particularly, to a heater for heating a wafer applied in a physical vapor deposition (PVD).

2. Description of the Prior Art

PVD processes have been widely applied to fabrication processes of ultra-large scale integrations (ULSI). Generally speaking, the PVD process utilizes inert gas, such as argon, to bombard a target material in high speed for sputtering atoms from the target. Then, the sputtered atoms of the target material, such as aluminum, titanium, or alloy thereof, evenly deposit on the surface of a wafer. The process chamber provides a vacuum environment with high temperature, thus the metal atoms deposited on the wafer become crystallized grains to form a metal layer. Lithography and etching processes are then performed to pattern the metal layer so that desired conductive circuits are observed. Generally, before performing the PVD process, the wafer is transferred to a degas chamber to undergo a degas process for pre-clean contaminations from a pre-layer process.

Please refer to FIG. 1. FIG. 1 is a section view of a heater 10 of a degas chamber according to the prior art. The heater 10 comprises a wafer loading plate 12 and a pedestal 14. The wafer loading plate 12 is formed with metal having high heat conductivity and has a larger area than the wafer 30 positioned on it. During the degas process, the wafer 30 is positioned on an upper surface 12a of the wafer loading plate 12. Therefore, the whole bottom surface of the wafer 30 contacts the upper surface 12a of the wafer loading plate 12, and the edge of the upper surface 12a of the wafer loading plate 12 protrudes from the wafer bevel 30a. The heater 10 provides heat energy to the wafer 30 through the upper surface 12a. Consequently, moisture and contaminations of the surface of the wafer 30 are vaporized because the temperature of the wafer 30 is raised. Similarly, the contaminations from pre-layer processes remained on the wafer bevel 30a are also vaporized resulted from the increased temperature and easily adhere to the upper surface 12a, which causes a black round coating on the edge of the upper surface 12a protruded from the wafer bevel 30a. As shown in FIG. 2, which is an outward schematic diagram of the heater 10 shown in FIG. 1. After running several times of degas processes to several wafers, a black round coating 16 occurs on the upper surface 12a.

In addition to contaminating the upper surface 12a of the heater 10, the black round coating 16 may also contaminate other wafers that are following loaded on the wafer loading plate 12. Accordingly, the workers have to stop the production process to clean the wafer loading plate 12 unscheduled to remove the black round coating 16 after performing several times of degas processes. Under this situation, the number of times and time cost of apparatus maintain cannot be decreased, and the process efficiency is deeply influenced, which raises the process cost and decrease the process yield.

### SUMMARY OF INVENTION

It is therefore a primary objective of the claimed invention to provide a heater that is hardly contaminated and a heating method thereof to solve the above-mentioned problem.

According to the claimed invention, a heater used for heating a wafer is disclosed. The heater is applied to a process chamber. The heater has an upper surface for loading the wafer so as to heat the wafer. When the wafer is positioned on the upper surface of the heater, the contact area between the upper surface of the heater and the wafer is less than the area of the wafer, and the upper surface of the heater does not contact the wafer bevel of the wafer.

According to the claimed invention, a method for preventing contamination of a heater is further disclosed. The heater is used for heating a wafer, and the method comprises not directly heating the wafer bevel when using the heater heating the wafer.

It is an advantage of the claimed invention that the area of the upper surface of the heater, which is a heating surface, is less than the area of the wafer, and the upper surface of the heater do not contact the wafer bevel, so that the vaporized contaminations can be removed from the heater by gas flow without causing a black round coating on the edge of the heater. Therefore, the frequency of apparatus maintain could be decreased so as to improve the process efficiency.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a section view of a heater of a degas chamber according to the prior art.

FIG. 2 is an outward schematic diagram of the heater shown in FIG. 1.

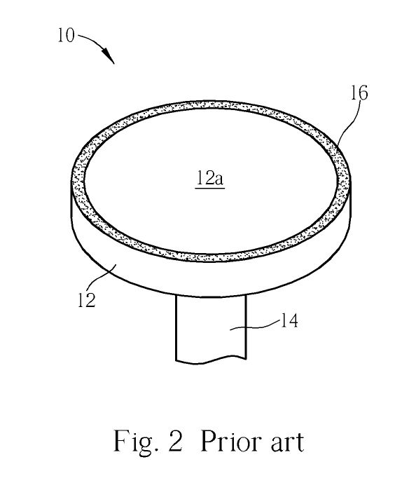

FIG. 3 is an outward schematic diagram of a heater according to the present invention.

FIG. 4 is a section view of the heater shown in FIG. 3.

FIG. 5 is a section view of a heater according to another embodiment of the present invention.

### DETAILED DESCRIPTION

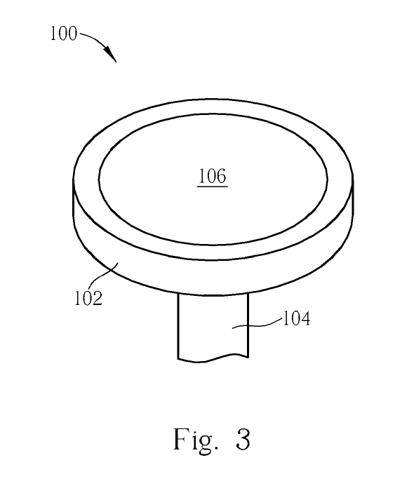

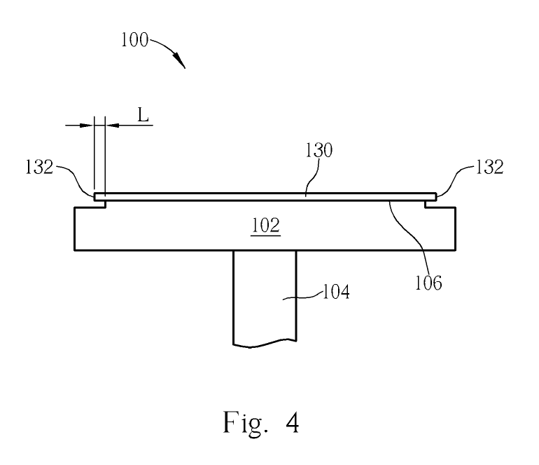

Please refer to FIG. 3 and FIG. 4. FIG. 3 is an outward schematic diagram of a heater 100 according to the present invention. FIG. 4 is a section view of the heater 100 shown in FIG. 3. The present invention heater 100 is applied to a PVD degas chamber of a semiconductor process, which comprises a wafer loading plate 102 and a pedestal 104. The wafer loading plate 102 is formed with metal having high heat conductivity. The upper surface of the wafer loading plate 102 is a wafer loading surface 106 for loading and directly contacting a wafer 130 positioned thereon, which provides heat energy to the wafer 130 by using resistance heating.

In contrast to the prior art, the wafer loading surface 106 of the heater 100 is cut inward along the edge of the wafer loading plate 102, which means the area of the wafer loading surface 106 is less than the bottom surface of the wafer loading plate 102. As shown in FIG. 4, the wafer loading surface 106 is designed according to making the wafer bevel 132 of the wafer 130 not contact the wafer loading surface 106 when the wafer 130 is positioned on the wafer loading surface 106. Referring to FIG. 4, when the wafer 130 is positioned on the wafer loading plate 102, the wafer loading surface 106 does not contact the wafer bevel 132, and the wafer bevel 132 overhangs the wafer loading surface 106 by a length L. In a preferable embodiment of the present invention, the length L is about 0.5-30 millimeters (mm). In a more preferable embodiment of the present invention, the length L is about 0.5-15 millimeters (mm).

Since the wafer bevel 132 of the wafer 130 does not contact the wafer loading surface 106 and overhangs the wafer loading plate 102, the wafer bevel 132 is not directly heated by the present invention heater 100 during the degas process. Thus, the gas containing contaminations below the overhanging wafer bevel 132 can be removed, and therefore the contaminations from the pre-layer processes on the wafer bevel 132 are hardly adhere to the wafer loading plate 102 and do not produce a black round coating.

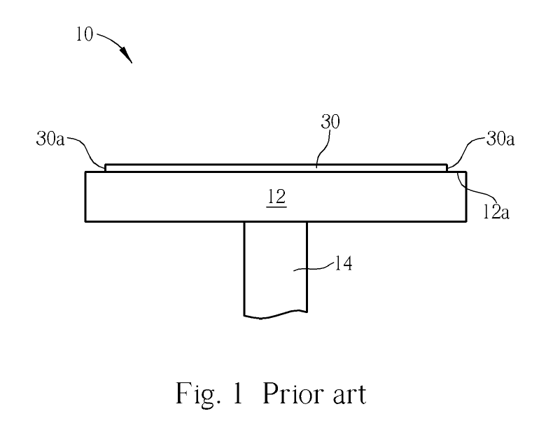

The fabricating method of the present invention heater 100 is to make a simple mechanism production to a prior-art heater with a flat wafer loading plate (for example, the heater 10 shown in FIG. 1). The upper surface of the wafer loading plate may be lathed and cut inward by the length L to make the radius of the upper surface of the wafer loading plate less than the radius of the wafer and the area of the upper surface less than that of the wafer, thus the present invention heater 100 having a function of preventing contaminations of the wafer bevel from polluting the upper surface of the wafer loading plate is formed. Therefore, the fabrication efficiency of the degas process is improved.

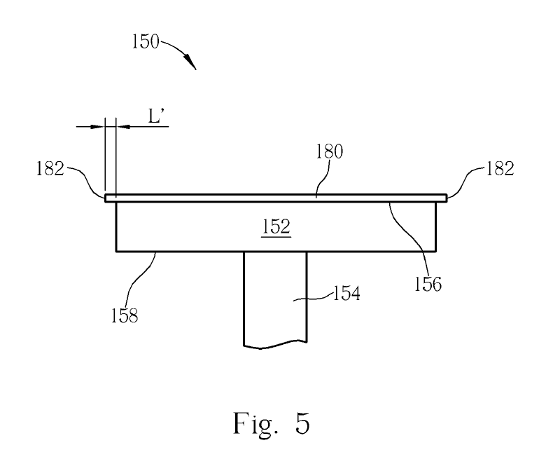

In addition, the present invention method further comprises directly fabricating a heater having a smaller size than the area of the wafer. Referring to FIG. 5, FIG. 5 is a section view of a heater 150 according to another embodiment of the present invention. The heater 150 has a wafer loading plate 152 and a pedestal 154, wherein the wafer loading plate 152 comprises an upper surface 156 serving as a heating surface for loading a wafer 180 and providing heat energy to the wafer 180 by directly contacting the wafer 180 during a degas process. It should be noted that the cross-section area of the whole wafer loading plate 152 is less than the area of the wafer 180, which means an area of the bottom surface 158 is equal to the area of the upper surface 156. Furthermore, the radius of the whole wafer loading plate 152 is less than the radius of the wafer 180 by a length L′. Accordingly, when the wafer 180 is positioned on the wafer loading plate 152, the contact area between the wafer 180 and the wafer loading plate 152 is less than the area of the wafer 180, and the wafer bevel 182 overhangs the wafer loading plate 152 without contacting the upper surface 156. Therefore, the wafer loading plate 152 is hardly contaminated by contaminations of the wafer bevel 182 during the degas process.

Those skilled in the art could realize that the spirit of the present invention is to make the wafer bevel not be directly heated by the way of heat transformation, irradiation, and convection when using the present invention heater to heat the wafer, so that the contamination to the heater can be prevented. By means of adjusting the contact area between the heater and the wafer, for example, making the wafer bevel without contacting the heater, the wafer bevel will not be heated directly by the heater to form black round coating in the edge of the upper surface of the heater.

In contrast to the prior art, the present invention heater has an advantage that its heating surface does not directly contact the wafer bevel of a wafer loaded thereon and the wafer bevel overhangs the heating surface when heating the wafer, so that the contaminations from pre-layer processes of the wafer bevel will be removed along gas flow without contaminating the heater. Accordingly, the workers do not have to stop production processes unscheduled for cleaning the heater, and therefore the process efficiency and yield will be improved.

Those skilled in the art will readily observe that numerous modifications and alterations of the device and method may be made while retaining the teachings of the invention. Accordingly, the above disclosure should be construed as limited only by the metes and bounds of the appended claims.

1. A heater for heating a wafer with a wafer bevel, the heater being applied to a process chamber and comprising an upper surface for positioning the wafer so as to heat the wafer, wherein when the wafer is positioned on the heater, a contact area between the upper surface and the wafer is less than the area of the wafer.

2. The heater of claim 1, wherein the area of the upper surface is less than the area of the wafer.

3. The heater of claim 1, wherein when the wafer is positioned on the upper surface of the heater, the wafer bevel overhangs an edge of the upper surface.

4. The heater of claim 3, wherein when the wafer is positioned on the upper surface of the heater, the wafer bevel overhangs the upper surface by 0.5-30 millimeters (mm).

5. The heater of claim 3, wherein when the wafer is positioned on the upper surface of the heater, the wafer bevel overhangs the upper surface by 0.5-15 mm.

6. The heater of claim 1, wherein when the wafer is positioned on the upper surface of the heater, the wafer bevel does not contact the heater.

7. The heater of claim 1, wherein the heater further comprises a lower surface, and the area of the lower surface is equal to the area of the upper surface.

8. The heater of claim 1, wherein the heater further comprises a lower surface, and the area of the lower surface is larger than the area of the upper surface.

9. The heater of claim 1, wherein the heater is applied to a physical vapor deposition (PVD) degas chamber.

10. A method for preventing contamination of a heater, wherein the heater is used for heating a wafer with a wafer bevel, the method comprising not directly heating the wafer bevel when using the heater to heat the wafer.

11. The method of claim 10, wherein the method comprises not directly heating the wafer bevel by the way of heat transformation, irradiation, and convection.

12. The method of claim 10, wherein the method further comprises making the wafer bevel not contact the heater when using the heater to heat the wafer.

13. The method of claim 10, wherein the heater has a heating surface for providing heat energy to the wafer, and the method further comprises making the area of the heating surface less than the area of the wafer.

14. The method of claim 10, wherein the heater has a heating surface for providing heat energy to the wafer, and the method further comprises making the wafer bevel overhang the heating surface when the wafer is positioned on the heater.

15. The method of claim 14, wherein the wafer bevel overhangs the heating surface by 0.5-30 mm.

16. The method of claim 14, wherein the wafer bevel overhangs the heating surface by 0.5-15 mm.

17. The method of claim 10, wherein the heater is applied to a process chamber.

18. The method of claim 10, wherein the heater is applied to a PVD degas chamber.
